(19) United States
(12) Patent Application Publication
(10) Pub. No.: US 2012/0175701 A1
(43) Pub. Date: Jul. 12, 2012

(54) SEMICONDUCTOR DEVICE AND METHOD FOR MANUFACTURING THE SAME

(75) Inventor: Hyung Jin PARK, Icheon (KR)

(73) Assignee: Hynix Semiconductor Inc., Icheon (KR)

(21) Appl. No.: 13/305,975

(22) Filed: Nov. 29, 2011

(30) Foreign Application Priority Data
Jan. 7, 2011 (KR) 10-2011-0001985

(51) Int. Cl. H01L 27/092; H01L 21/20

(52) U.S. Cl. 257/334; 438/478; 257/E27.062; 257/E21.09

(57) ABSTRACT

A semiconductor device and a method for manufacturing the same are disclosed, in which a gate formed over a device isolation film is an inner gate inserted into a recess so that device operation characteristics are improved. A semiconductor device includes a recess formed in a device isolation film of a semiconductor substrate including an active region and the device isolation film, a gate formed over the recess and having a width smaller than that of the recess, and a capping film formed over a sidewall of a gate including the recess exposed by the gate.

### CROSS-REFERENCE TO RELATED APPLICATION

The priority of Korean patent application No. 10-2011-0001985 filed on 7 Jan. 2011, the disclosure of which is hereby incorporated in its entirety by reference, is claimed.

### BACKGROUND OF THE INVENTION

Embodiments of the present invention relate to a semiconductor device and a method for manufacturing the same, and more particularly to a semiconductor device including a fin-type gate and a method for manufacturing the same.

With the increasing integration degree of semiconductor devices, a planar gate process for forming a gate in a planar active region generates a junction leakage current caused by the increase of an electric field due to reduced gate channel length and increased ion-implantation doping density, so that it is difficult to ensure adequate refresh characteristics of the device.

In order to overcome the above-mentioned problem, a three-dimensional gate process for forming a gate in a three-dimensional (3D) active region has been proposed.

A variety of processes have been used as a three-dimensional gate process; for example, a recess gate process for recessing an active region of a specific part in which a gate is to be formed and forming the gate over the specific part, a fin gate process for recessing a device isolation film to make the active region protrude in a fin form and forming the gate over the protruded active region, and a saddle gate process for mixing the recess gate process and the fin-gate process.

If misalignment between the recessed region and the gate occurs in a 3D gate, a process margin for a subsequent etching process is reduced, so that there is a high possibility of failing to electrically couple a lower gate formed over a device isolation film to a landing plug contact.

In addition, if an etch process for forming the landing plug contact is excessively carried out, a device isolation film and the bottom of the active region are increased in size, such that the resultant landing plug contact may be electrically short-circuited to a neighboring gate. On the contrary, if an etch process for forming the landing plug contact is insufficiently carried out, it is difficult to guarantee an open area of the resultant landing plug contact hole.

### BRIEF SUMMARY OF THE INVENTION

Various embodiments of the present invention are directed to providing a semiconductor device and a method for manufacturing the same that substantially obviates one or more problems due to limitations and disadvantages of the related art.

An embodiment of the present invention relates to a semiconductor device which configures a gate formed over a device isolation film in the form of an inner gate inserted into a recess so as to improve device operation characteristics, and a method for forming the same.

In accordance with an aspect of the present invention, A semiconductor device comprising: a semiconductor substrate including an active region and a device isolation film; a first recess formed in the device isolation film; a gate formed over the first recess and having a width smaller than that of the recess; and a capping film formed over a sidewall of a gate including a first space between a first sidewall of the gate and a first sidewall of the recess.

The capping film is formed over a second space between a second sidewall of the gate and a second sidewall of the recess.

One or more capping films are buried in the first space.

A second recess formed in the device isolation film symmetrical to the first recess.

The capping film includes a nitride film.

Further comprising: a third recess formed in the active region; and a gate formed over the third recess, and having a width equal to or larger than a width of the third recess.

The width of the first recess is larger than the width of the third recess.

The width of the gate formed over the first recess is smaller than the width of the gate formed over the third recess.

The first space has a depth equal to or lower than the depth of the first recess.

In accordance with another aspect of the present invention, a method for manufacturing a semiconductor device comprising: forming a semiconductor substrate including an active region and a device isolation film; forming a first recess by etching the device isolation film; forming a gate over the first recess such that a first space between a first sidewall of the gate and a first sidewall of the first recess, the gate having a width smaller than a width of the first recess; and forming a capping film over a first space.

The formation of the gate includes exposing both sidewalls of the first recess.

The formation of the gate includes exposing one sidewall of the first recess.

Further including forming a second gate over a second recess parallel to the first recess such that a sidewall of the second recess is exposed, and the exposed sidewall of the second recess faces the exposed sidewall of the first recess.

The formation of the capping film includes: depositing a nitride film over the entire surface of the semiconductor substrate including the first space and the gate.

The first space has a depth equal to or lower than the depth of the first recess.

Further comprising: forming a second recess by etching the active region of the semiconductor substrate; and forming a gate over the second recess, wherein the gate has a width equal to or larger than a width of the second recess.

The width of the first recess is larger than the width of the second recess.

The width of the gate of the first recess is smaller than the width of the gate of the second recess.

It is to be understood that both the foregoing general description and the following detailed description of the present invention are exemplary and explanatory and are intended to provide further explanation of the invention as claimed.

### BRIEF DESCRIPTION OF THE DRAWINGS

FIGS. 1A to 1C are layout and cross-sectional views illustrating a semiconductor device and a method for manufacturing the same according to an embodiment of the present invention.

FIGS. 2A to 2C are layout and cross-sectional views illustrating a semiconductor device and a method for manufacturing the same according to another embodiment of the present invention.

### DESCRIPTION OF EMBODIMENTS

Reference will now be made in detail to embodiments of the present invention, examples of which are illustrated in the accompanying drawings. Wherever possible, the same reference numbers will be used throughout the drawings to refer to the same or like parts. A semiconductor device and a method for manufacturing the same according to embodiments of the present invention will hereinafter be described with reference to the accompanying drawings.

Embodiments of the present invention configure a gate formed over a device isolation film in the form of an inner gate inserted into a recess. The width of the inner gate is less than the width of the recess over which the inner gate is formed. A semiconductor device layout according to an embodiment of the present invention will hereinafter be described with reference to the attached drawings.

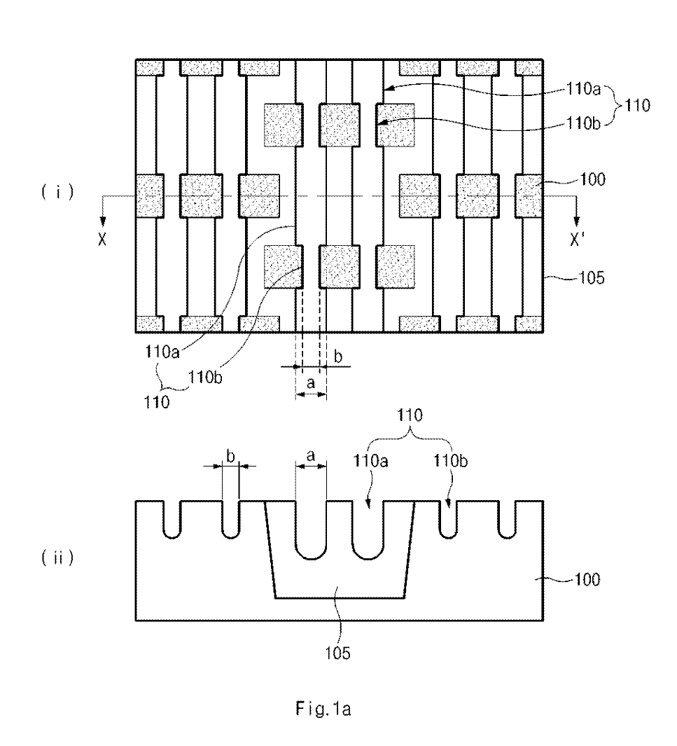

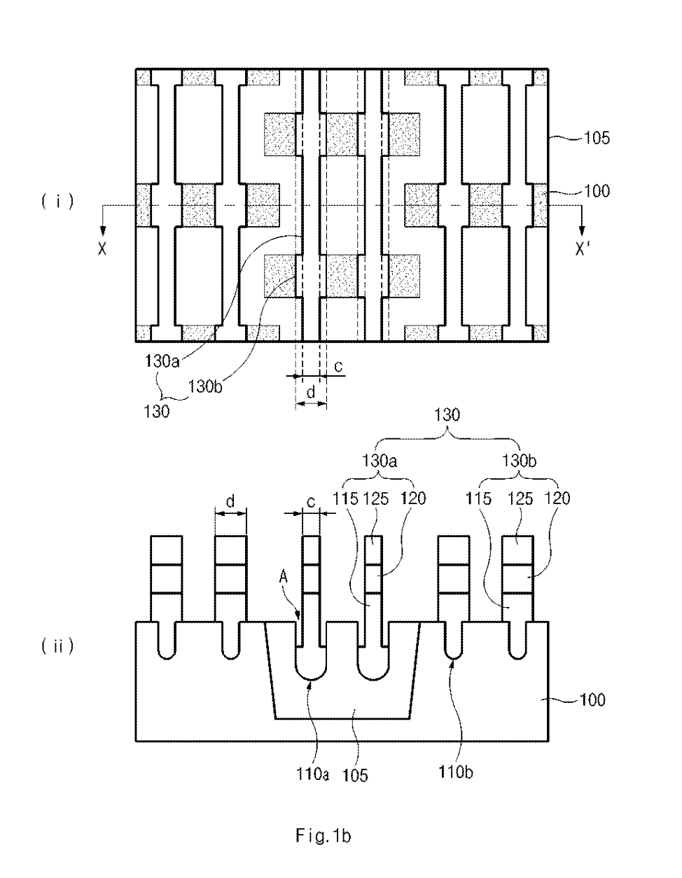

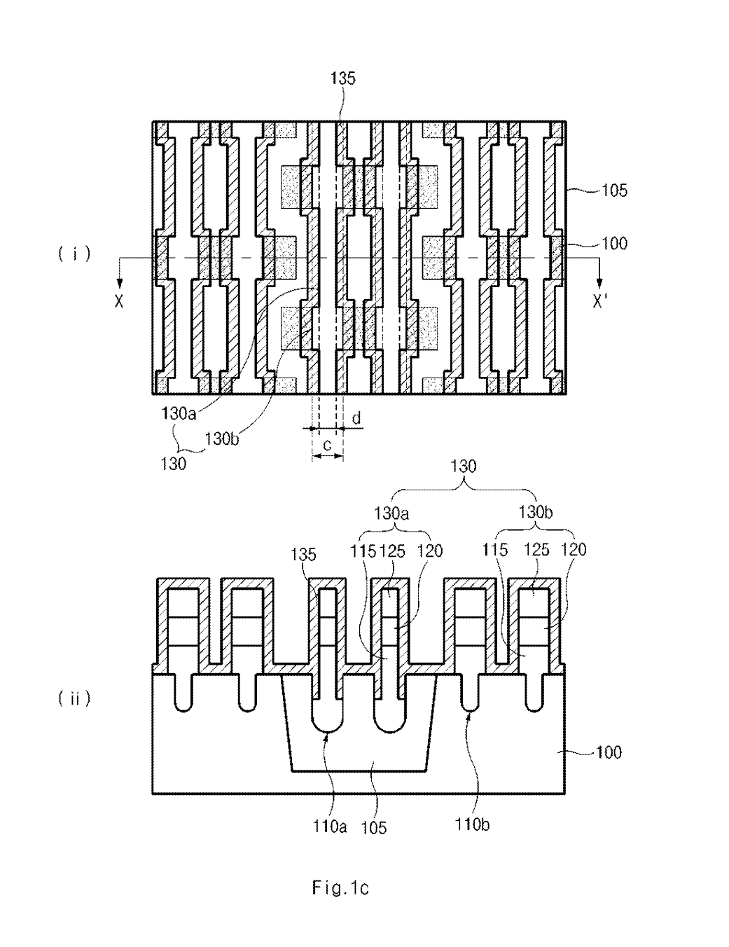

FIGS. 1A to 1C are layout and cross-sectional views illustrating a semiconductor device and a method for manufacturing the same according to an embodiment of the present invention. In each of FIGS. 1A to 1C, (i) is a layout of a semiconductor device, and (ii) is a cross-sectional view illustrating a semiconductor device taken along the line X-X′ of FIG. 1A(i), 1B(i) or 1C(i).

Referring to FIG. 1A(i), a plurality of bar-shaped active regions 100 are formed in a semiconductor substrate, and device isolation films 105 defining each active region 100 are formed. In addition, the semiconductor device includes two line-shaped recesses 110 passing through each active region 100. In this implementation, the recess 110 is formed to pass through a specific area in which a gate is to be formed in a subsequent process. One recess 110 may have different widths for portions of the recess passing through the device isolation film 105 and portions of the recess passing through the active region 100. For example, referring to FIG. 1A(i), a width (a) of a first recess 110a formed in the device isolation film 105 may be larger than a width (b) of a second recess 110b formed in the active region 100. Specifically, the first recess 110a formed in the device isolation film 105 may be formed to have a width (a) of 40˜45 nm, and the second recess 110b formed in the active region 100 may be formed to have a width (b) of 25˜30 nm. In another embodiment, portions of the recess formed in the active region 100 and portions of the recess formed in the device isolation film 105 may have the same width.

A method for forming the device isolation film 105 and the recess 100 will hereinafter be described with reference to FIG. 1A(ii). A semiconductor substrate is etched so that a device isolation trench defining the active region 100 is formed and an insulation film is buried in the device isolation trench. Thereafter, a planarization process is performed until the semiconductor substrate is exposed, so that the device isolation film 105 is formed. The insulation film may be formed of a material including an oxide film.

A mask pattern (not shown) for defining a recess is formed over the active region 100 and the device isolation film 105. The mask pattern (not shown) is formed by a photolithography process using a fin-shaped gate mask or a recess-shaped gate mask. Thereafter, the device isolation film 105 and the active region 100 are etched using the mask pattern (not shown) as an etch mask so that the first recess 110a and the second recess 110b are formed. In this implementation, the device isolation film 105 formed of an oxide material has an etch selection ratio higher than that the active region 100 formed of silicon, so that the first recess 110a formed in the device isolation film 105 is deeper than the second recess 110b formed in the active region 100. The above-mentioned recess 110, which includes a shallower first recess 110a formed in the device isolation film 105 and a deeper second recess 110b formed in the active region 100, is referred to as a fin-type recess.

Referring to FIG. 1B(i), gates 130 are formed over an upper part of the recess 110. A gate 130 formed over the device isolation film 105 is defined as a first gate 130a, and a gate 130 formed over the active region 100 is defined as a second gate 130b. In an embodiment, a width (c) of the first gate 130a may be different from a width (d) of the second gate 130b. In more detail, the width (c) of the first gate 130a formed over the device isolation film 105 may be smaller than the width (a) of the first recess 110a of FIG. 1A. In the active region 100, a width (d) of a second gate 130b of FIG. 1B may be larger than a width (b) of a second recess 110b of FIG. 1A.

A method for forming the gate 130 according to an embodiment of the present invention will hereinafter be described with reference to FIG. 1B(ii). A gate polysilicon layer 115, a gate metal layer 120, and a gate hard mask layer 125 are sequentially formed over the semiconductor substrate including the first recess 110a and the second recess 110b. The gate metal layer 120 may include tungsten (W), tungsten silicide (WSix), or a combination thereof, and the gate hard mask layer 125 may include a nitride film.

Thereafter, the gate hard mask layer, the gate metal layer 120, and the gate polysilicon layer 115 are etched so that the first gate 130a is formed over the device isolation film 105 and the second gate 130b is formed over the active region 100. In this implementation, the first gate 130a may be formed over the first recess 110a, and the second gate 130b may be formed over the second recess 110b. In addition, a width (c) of the first gate 130a may be different from a width (d) of the second gate 130b. A width (c) of the first gate 130a formed over the device isolation film 105 may be smaller than the width (a) of the first recess 110a of FIG. 1A. In the active region 100, the width (d) of the second gate 130b of FIG. 1A may be larger than the width (b) of the second recess 110b of FIG. 1A.

As described above, the width of the first gate 130a may be smaller than that of the first recess 110a formed in the device isolation film 105. Therefore, during a gate etching process, a gate polysilicon layer 115 deposited at a lower part is partially etched, so that a groove ‘A’ shown in FIG. 1B(ii) is formed between a sidewall of the first recess 110a and the first gate 130a.

Referring to FIG. 1C, a capping film 135 is formed over the entire semiconductor substrate including the first gate 130a and the second gate 130b. In this implementation, the capping film 135 fills groove A that is located between the first gate 130a formed over the device isolation film and the first recess 110a. The capping film 135 may include a nitride film. As described above, the first gate 130a formed over the device isolation film 105 is configured in the form of an inner gate inserted into the first recess 110a, and the capping film 135 is formed between the first recess 110a and the first gate 130a, so that a process margin requisite for an etch process forming a landing plug contact hole in a subsequent process can be improved. Specifically, the capping film 135 is formed at a predetermined position between the first recess 110a and the first gate 130a, so that a margin for locating a gate relative to a landing plug is improved, thereby preventing the occurrence of an SAC failure. A landing plug contact hole for a bit line contact plug may be formed over the position between the first recess 110a and the first gate 130a in a subsequent process.

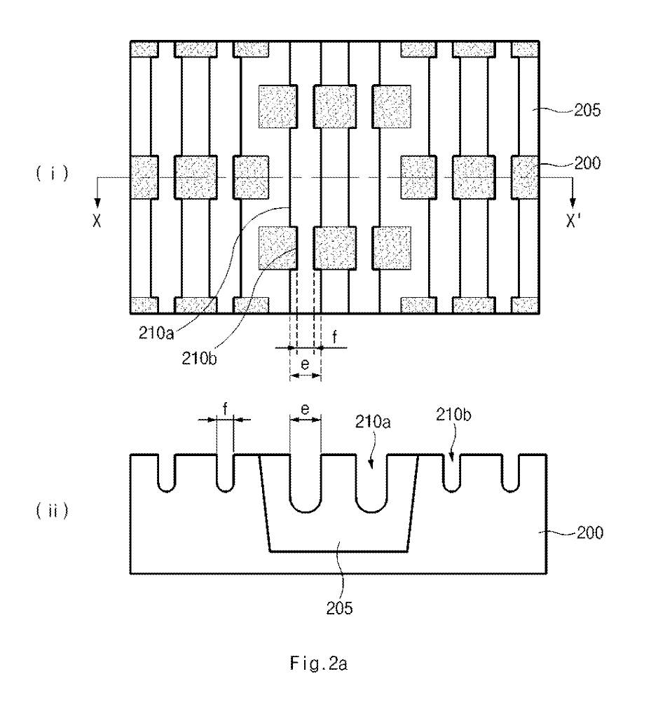

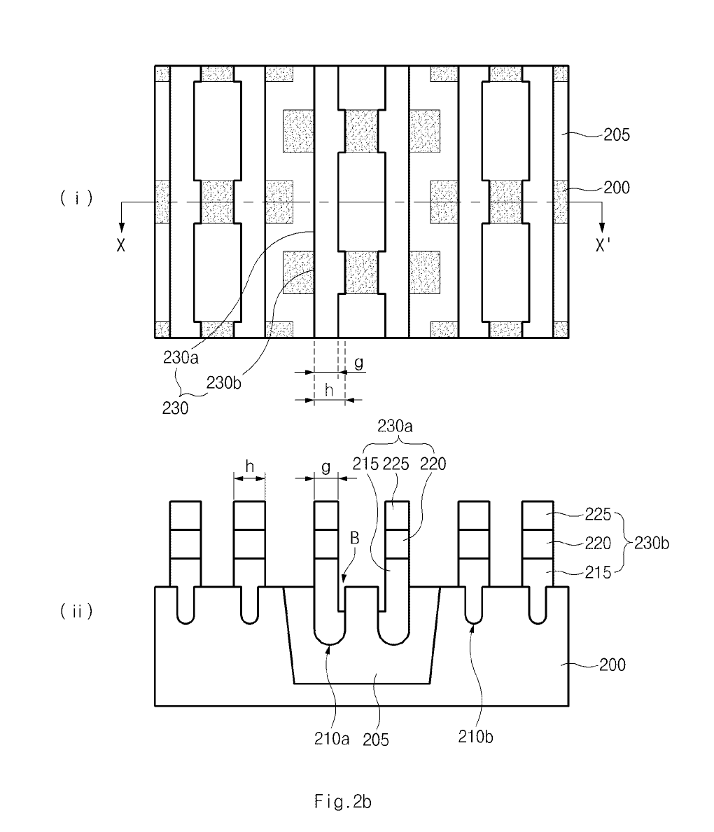

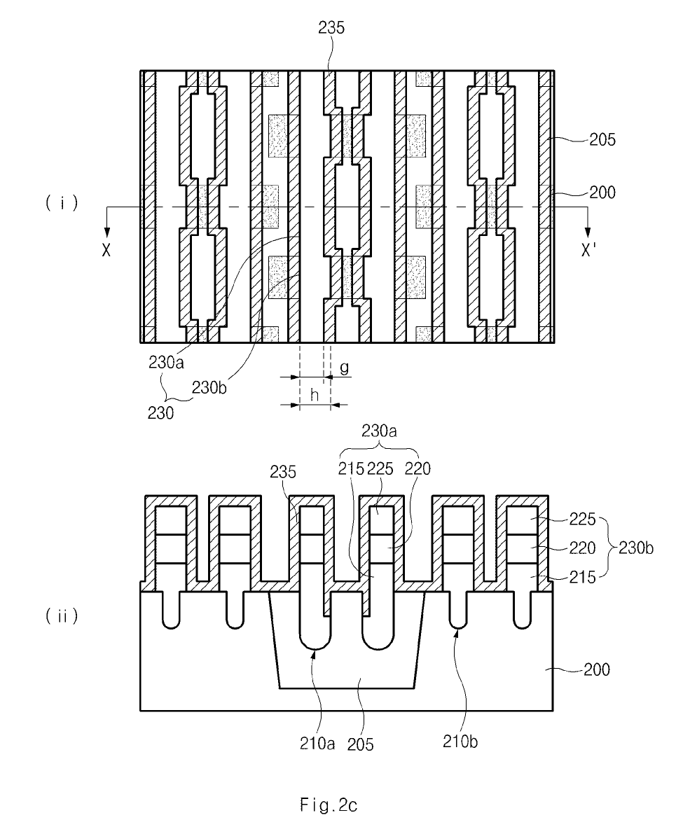

FIGS. 2A to 2C are layout and cross-sectional views illustrating a semiconductor device and a method for manufacturing the same according to another embodiment of the present invention. In each of FIGS. 2A to 2C, (i) is a layout of a semiconductor device, and (ii) is a cross-sectional view illustrating a semiconductor device taken along the line X-X′ of FIG. 2A(i), 2B(i) or 2C(i).

Referring to FIG. 2A, a semiconductor substrate including an active region 200 and a device isolation film 205 is etched, so that a first recess 210a is formed in the device isolation film 205 and a second recess 210b is formed in the active region 200. In this implementation, a width (e) of the first recess 210a is larger than a width (f) of the second recess 210b. The active region 200, the device isolation film 205, the first recess 210a, and the second recess 210b are formed with the same characteristics and methods described with respect to FIG. 1A, so a detailed description thereof is omitted.

Referring to FIG. 2B(i), a width (h) of a first gate 230a formed over the device isolation film 205 is smaller than a width (g) of the second gate 230b passing the active region 200. In more detail, a first sidewall of the first gate 230a is coplanar with a sidewall of the second gate 230b, while a second sidewall of the first gate 230a is stepped inward with respect to the second gate 230b. The resulting gate structure 230 has a first sidewall running in a straight line, while the second sidewall is disposed such that the gate is wider over an active region than an isolation region, as shown in FIG. 2B(i). In this implementation, two gates 230 are disposed over one active region 200 and are symmetrical to one another with respect to a vertical plane. In an embodiment, the second sidewall of the first gate 230a may be formed in a concave structure, so that the concave sidewalls of plural first gates 230a may be arranged to face each other in one active region 200.

A method for forming the gate 230 will hereinafter be described with reference to FIG. 2B(ii). Referring to FIG. 2B(ii), a gate polysilicon layer 215, a gate metal layer 220, and a gate hard mask layer 225 are sequentially formed over the semiconductor substrate including the first recess 210a and the second recess 210b. The gate metal layer 220 may include tungsten (W), tungsten silicide (WSix), or a combination thereof, and the gate hard mask layer 225 may include a nitride film. Subsequently, the gate hard mask layer 225, the gate metal layer 220, and the gate polysilicon layer 215 are etched so that the first gate 230a is formed over the device isolation film 205 and the second gate 230b is formed over the active region 200. In this implementation, the gate polysilicon layer 215 is further etched, so that a groove B is formed in the first recess 210a. That is, a groove B is formed on the facing sides of two first gates 230a formed over the device isolation film 205. Referring to FIG. 2C, a capping film 235 is formed over the entirety of the semiconductor substrate including the first gate 230a and the second gate 230b. In this implementation, the capping film 235 may completely fill the groove B formed at facing sidewalls of the first recesses 210a.

As is apparent from the above description, for a semiconductor device and a method for manufacturing the same according to an embodiment of the present invention, the first gate 230a formed over the device isolation film 205 is formed over the first recess 210a so that an inner gate is formed. The capping film 235 is formed in a space between the first recess 210a and the first gate 230a, so that an adequate process margin can be ensured in a subsequent etch process for forming a landing plug contact hole. Specifically, the capping film 235 is formed in a space between a sidewall of the first recess 210a and a sidewall of the first gate 230a. At the reserved region, a landing plug contact hole for a bit line contact plug may be formed over the space region in a subsequent process. As a result, a space margin between a gate and a landing plug is increased in order to prevent the occurrence of an SAC failure.

The above embodiments of the present invention are illustrative and not limitative. Various alternatives and equivalents are possible. The invention is not limited by the embodiments described herein. Nor is the invention limited to any specific type of semiconductor device. Other additions, subtractions, or modifications are obvious in view of the present disclosure and are intended to fall within the scope of the appended claims.

What is claimed is:

1. A semiconductor device comprising:
a semiconductor substrate including an active region and a device isolation film;
a first recess formed in the device isolation film;
a first gate formed over the first recess and having a width smaller than that of the recess;
a first space disposed between a first sidewall of the first gate and a first sidewall of the first recess; and
a capping film formed in the first space.

2. The semiconductor device according to claim 1 further comprising a second space disposed between a second sidewall of the first gate and a second sidewall of the first recess, wherein the capping film is formed in the second space.

3. The semiconductor device according to claim 1, wherein a plurality of capping films are formed over the first space.

4. The semiconductor device according to claim 1, further comprising a second recess formed in the device isolation film, and symmetrical to the first recess.

5. The semiconductor device according to claim 1, wherein the capping film includes a nitride film.

6. The semiconductor device according to claim 1, further comprising:
a third recess formed in the active region; and
a third gate formed over the third recess, and having a width equal to or larger than a width of the third recess.

7. The semiconductor device according to claim 6, wherein the width of the first recess is larger than the width of the third recess.

8. The semiconductor device according to claim 6, wherein the width of the first gate is smaller than the width of the third gate.

9. The semiconductor device according to claim 6, wherein the first recess has a depth equal to or greater than a depth of the third recess.

10. A method for manufacturing a semiconductor device comprising:
forming a semiconductor substrate including an active region and a device isolation film;
forming a first recess by etching the device isolation film;
forming a first gate over the first recess such that a first space is formed between a first sidewall of the first gate and a first sidewall of the first recess, the first gate having a width smaller than a width of the first recess; and
forming a capping film in the first space.

11. The method according to claim 10, wherein the formation of the gate includes forming a second space between a second sidewall of the first gate and a second sidewall of the first recess.

12. The method according to claim 10, wherein there is no space between a second sidewall of the first gate and a second sidewall of the first recess.

13. The method according to claim 12, further including:
forming a second recess, parallel to the first recess, by etching the device isolation film;
forming a second gate over the second recess; and
forming a second space between a first sidewall of the second gate and a first sidewall of the second recess,
wherein the first sidewall of the second gate faces the first sidewall of the first gate.

14. The method according to claim 10, wherein the formation of the capping film includes:
depositing a nitride film over an entire surface of the semiconductor substrate including the first space and the first gate.

15. The method according to claim 10, further comprising:
forming a third recess by etching the active region of the semiconductor substrate; and
forming a third gate over the third recess, wherein the third gate has a width equal to or larger than a width of the third recess.

16. The method according to claim 15, wherein the width of the first recess is larger than the width of the third recess.

17. The method according to claim 15, wherein the width of the first gate is smaller than the width of the third gate.

18. The method according to claim 15, wherein a depth of the first recess is greater than or equal to a depth of the third recess.
